(19) United States
(12) Patent Application Publication
(10) Pub. No.: US 2013/0058055 A1
(43) Pub. Date: Mar. 7, 2013

(54) SUBSTRATE WITH BUILT-IN COMPONENT

(71) Applicant: Murata Manufacturing Co., Ltd., Nagaokakyo-shi (JP)

(72) Inventor: Yuki YAMAMOTO, Nagaokakyo-shi (JP)

(73) Assignee: MURATA MANUFACTURING CO., LTD., Nagaokakyo-shi (JP)

(21) Appl. No.: 13/665,977

(22) Filed: Nov. 1, 2012

Related U.S. Application Data
(63) Continuation of application No. PCT/JP2011/002874, filed on May 24, 2011.

(30) Foreign Application Priority Data
May 26, 2010 (JP) 2010-120326

(51) Int. Cl. H05K 1/00; H05K 7/00; H05K 1/09

(52) U.S. Cl. 361/748; 174/258; 174/257

(57) ABSTRACT

A substrate with a built-in component is constructed such that a resin reliably goes around a clearance provided in a lower portion of the component and is thus filled in without expansion of a clearance in a height direction when various components such as an LW reversal type chip component are to be built in. The substrate includes a component to be embedded in a resin layer, and a land electrode (a component mounting electrode) to which external electrodes of the component are to be bonded, the land electrode being provided with a concave groove extending in a transverse direction through which an uncured resin of the resin layer flows, and the uncured resin of the resin layer flows through the concave groove and sufficiently goes around a lower side of the component so that the resin is well filled in when the component in a mounting state is to be embedded in the resin layer.

### BACKGROUND OF THE INVENTION

1. Field of the Invention

The present invention relates to a substrate with a built-in component which includes, in a resin layer, a component (an electronic component) such as a so-called LW reversal type capacitor, and relates more particularly, to an improvement in resin filling under the component.

2. Description of the Related Art

As a substrate with a built-in component (which is also referred to as a module with a built-in component), conventionally, there is known a structure in which a component is mounted on a core board and is embedded in a resin layer. See, for example, see Japanese Laid-Open Patent Publication No. 2004-342859, especially paragraphs [0022] to [0026] and FIG. 4.

In many cases, the resin layer of the substrate with a built-in component which has the above structure is formed by a thermosetting resin or a thermoplastic resin.

FIGS. 9A to 9C are sectional views showing an example of a method of manufacturing the substrate with a built-in component described in Japanese Laid-Open Patent Publication No. 2004-342859. In the example of the method of manufacturing, first of all, a semicuring resin sheet 101 shown in FIG. 9A is prepared. The semicuring resin sheet 101 is a thermosetting epoxy resin sheet containing an inorganic filler, for example, and forms the resin layer, and a protective film 102 is laminated on both sides thereof. The protective film 102 is a thin film formed of polyethylene terephthalate (PET), polyphenylene sulfide (PPS) or the like. Furthermore, a via hole 108 for interlayer connection is formed in a predetermined place of the semicuring resin sheet 101 and a conductive paste 109 is filled in the via hole 108 by a screen printing method or the like.

As shown in FIG. 9B, next, the protective film 102 is peeled and removed, and a prepared circuit board 110 is then bonded to upper and lower portions of the semicuring resin sheet 101 in such a state that a via connecting land (a substrate electrode) 112 formed on a surface of each circuit board 110 is aligned with the via hole 108 formed on the semicuring resin sheet 101, for example. The circuit board 110 on a lower side is a core board and a component 111 is mounted on the core board.

The upper and lower circuit boards 110 and the semicuring resin sheet 101 are heated to 180° C. and are pressed, for example. At this time, the semicuring resin sheet 101 is once softened and is expanded as shown in an arrow line of FIG. 9C so that the component 111 is embedded in the semicuring resin sheet 101. Thereafter, the semicuring resin sheet 101 and the conductive paste 109 are cured so that a substrate with a built-in component 100 is obtained.

As the substrate with a built-in component of this type, there is also known a coreless board structure in which the core board such as the lower circuit board 110 is omitted.

Examples of the component 111 provided in the resin layer of the substrate with a built-in component of this type include various electronic components such as a capacitor, a coil (an inductor), a transistor or an integrated circuit. As a chip component having a rectangular parallelepiped shape in which a mounting surface is rectangular, for example, a chip capacitor, particularly, there is known an LW reversal type in which an external electrode is formed on respective surfaces provided in contact with two long sides of the mounting surface. See, for example, Japanese Laid-Open Patent Publication No. 2009-27148, especially paragraphs [0007] and [0008].

FIGS. 10A and 10B are perspective and plan views showing a normal chip capacitor 200. In the chip capacitor 200 having a rectangular shape, an external electrode 202 is formed on both ends of a body portion 201 on the mounting surface (respective surfaces provided in contact with two short sides of the mounting surface).

In the chip capacitor 200, lengths of two sides at the short side of the mounting surface where the external electrode 202 is to be formed are referred to as a W size, lengths of two sides on a long side (a longitudinal direction) which is orthogonal thereto are referred to as an L size, a width of the external electrode 202 is referred to as an e size, and a length of the body portion 201 between the external electrodes 102 is referred to as a g size. In the case of a normal chip component, L>W is obtained as is apparent from FIGS. 10A and 10B.

FIGS. 11A and 11B are perspective and plan views showing an LW reversal type chip capacitor 300. In the chip capacitor 300, an external electrode 302 is formed on both end surfaces of a body portion 301 on the mounting surface (respective surfaces provided in contact with two long sides of the mounting surface).

For this reason, in the chip capacitor 300, lengths (W size) of two surfaces where the external electrode 302 is to be formed are greater than lengths (L size) of two side surfaces which are orthogonal thereto, L<W is obtained as is apparent from FIGS. 11A and 11B, and a relationship between the L and W sizes is reverse to that of the normal chip capacitor 200 and the g size is also smaller than that of the normal chip capacitor 200.

The LW reversal type chip capacitor 300 has a small ESL (Equivalent Series Inductance) and is useful as a capacitor for the purpose of decoupling in the ESL of various semiconductor circuits in which an increase in a speed and a reduction in a driving voltage are advanced.

In the case in which the LW reversal type chip capacitor 300 is provided as the component 111 in the substrate with a built-in component 100 in FIGS. 9A-9C, for example, a slender bottleneck-shaped clearance interposed between the external electrodes 302 is formed on a lower side (a core board side) when the chip capacitor 300 is mounted on the core board (the circuit board 110 on a lower side) because of L<W and a small g size. For this reason, in a process for embedding the chip capacitor 300 in the resin layer after mounting the chip capacitor 300 on the substrate, a resin of an uncured (semicured) resin layer does not sufficiently go around the clearance even if the resin is expanded by heating and pressing. Consequently, a filling failure occurs, resulting in a defect such as a solder flash caused by a subsequent reflow treatment.

In various LW reversal type chip components as well as the chip capacitor 300, a drawback is caused by the filling failure of the resin.

FIGS. 12A and 12B are sectional views showing a substrate with a built-in component 400, illustrating an example of the defect, and a bottom view showing a resin filling state of a chip component 402 seen from an upper surface of a core board 401. For example, in the LW reversal type chip component 402 such as the chip capacitor 300, an external electrode 404 is bonded to each land electrode 406 on an upper surface of the core board 401 through a bonding material 405 such as a solder and is thus mounted on the core board 401.

Each land electrode 406 on the upper surface of the core board 401 is connected to a lower electrode 408 of the core board 401 through a via conductor 407 penetrating the core board 401.

Furthermore, the chip component 402 is embedded and provided in a resin layer 409 such as the semicuring resin sheet 101 in FIGS. 9A-9C. However, an uncured (a semicured) resin 409a before curing the resin layer 409 does not perfectly go around a slender bottleneck-shaped clearance α portion interposed between the external electrodes 404 of the two sides at the lower side of the chip component 402 by the heating and pressing as shown in FIG. 12B. Consequently, a filling failure occurs so that a defect is caused.

In order to prevent the filling failure from occurring, it has been proposed to increase an application amount of the solder serving as the bonding material 405 and to push the chip component 402 up by a surface tension thereof, thereby enlarging the clearance α in a height direction in component mounting, for example.

FIG. 13 is a sectional view showing a substrate with a built-in component 500 formed with an increase in the application amount of the solder to be the bonding material 405. As is apparent from a comparison to the substrate with a built-in component 400 in FIG. 12A, in the substrate with a built-in component 500, the bonding material 405 pushes the chip component 402 up so that the clearance α is enlarged in the height direction. In the substrate with a built-in component 500, therefore, the resin easily goes around the lower side of the chip component 402 so that a filling failure of the resin is prevented from occurring.

However, the substrate with a built-in component 500 is more bulky than the substrate with a built-in component 400. Accordingly, the increase in the application amount of the solder to be the bonding material 405 to enlarge the clearance α on the lower side of the chip component 402 in the height direction cannot meet a demand for a reduction in a height (a reduction in a size), which is not practical.

A drawback is caused by the filling failure of the resin when a mounting area on the lower side of the component is large in a substrate with a built-in component which includes a normal chip component having L>W or the like as well as a substrate with a built-in component which includes an LW reversal type chip component.

Also in the case of a coreless board structure in which a core board is omitted from the substrate with a built-in component, furthermore, the drawback is caused by the filling failure of the resin.

### SUMMARY OF THE INVENTION

Preferred embodiments of the present invention ensure that a resin to reliably goes around a clearance provided on a lower side of a component and is filled without an increase in a clearance in a height direction when various components such as an LW reversal type chip component are to be built in a substrate with a built-in component of this type.

A substrate with a built-in component according to a preferred embodiment of the present invention includes a component to be embedded in a resin layer, and a component mounting electrode to which an external electrode of the component is to be bonded, and the component mounting electrode is provided with a concave groove through which an uncured resin of the resin layer flows in a transverse direction.

The component mounting electrode preferably includes a plurality of split electrodes arranged along a vertical line, and the concave groove is defined by a clearance provided between the respective split electrodes.

Furthermore, the component mounting electrode preferably has a rectangular or substantially rectangular shape, and the concave groove is arranged to extend in a perpendicular or substantially perpendicular direction relative to a long side of the mounting electrode.

In addition, the substrate with a built-in component according to a preferred embodiment of the present invention is preferably constructed such that the component has a rectangular or substantially parallelepiped shape, and has a structure in which the external electrode is located on respective surfaces provided in contact with two long sides of a rectangular or substantially rectangular mounting surface.

Moreover, according to a preferred embodiment of the present invention, the component preferably is a chip capacitor that has a rectangular or substantially rectangular parallelepiped shape.

According to a preferred embodiment of the present invention, the concave groove in the transverse direction is located on the component mounting electrode. When the component mounted by bonding the external electrode to the component mounting electrode is to be embedded in the resin layer, therefore, the uncured resin of the resin layer flows through the concave groove and sufficiently goes around the lower side of the component so that the resin is well filled in the clearance provided on the lower side of the component without expanding the clearance to be bulky in the height direction.

Accordingly, the resin can be caused to reliably go around the clearance provided on the lower side of the component and can be thus filled in. Consequently, it is possible to enhance the filling state of the resin, thereby preventing an occurrence of a defect such as a solder flash in subsequent reflow.

According to a preferred embodiment of the present invention, the component mounting electrode preferably includes a plurality of split electrodes. Consequently, it is possible to easily form the concave groove by the clearance provided between the split electrodes, thereby obtaining advantageous effects.

According to a preferred embodiment of the present invention, the concave groove is preferably arranged to extend in a direction that is perpendicular or substantially perpendicular to the long side of the component mounting electrode that has an elongated rectangular or substantially rectangular shape. Consequently, it is possible to cause the uncured resin to flow through the concave groove, thereby obtaining advantageous effects.

According to a preferred embodiment of the present invention, the clearance provided between the external electrodes provided under the component preferably is slender bottleneck-shaped, and particularly, the resin goes around with difficulty. However, the concave groove is formed so that the resin flows through the concave groove, and sufficiently goes around the clearance provided on the lower side of the component and is thus filled in. Thus, it is possible to obtain advantageous effects.

According to a preferred embodiment of the present invention, the LW reversal type chip component preferably is a chip capacitor that has a rectangular or substantially rectangular parallelepiped shape.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B are sectional views showing a side surface and an end surface of a substrate with a built-in component which has a core board according to a first preferred embodiment of the present invention.

FIGS. 2A to 2C are views for explaining a filling state of a resin in the substrate with a built-in component in FIG. 1.

FIG. 3 is a sectional view showing a substrate with a built-in component of a coreless board according to a second preferred embodiment of the present invention.

FIG. 4 is a view for explaining a concave groove of the substrate with a built-in component in FIG. 3.

FIGS. 5A to 5E are sectional views for explaining a process for manufacturing the substrate with a built-in component in FIG. 3.

FIG. 6 is a sectional view showing a portion of a substrate with a built-in component according to a third preferred embodiment of the present invention.

FIGS. 7A and 7B are views for explaining another example of the concave groove according to a preferred embodiment of the present invention, respectively.

FIG. 8 is a view for explaining a further example of the concave groove according to a preferred embodiment of the present invention.

FIGS. 9A to 9C are sectional views for explaining a process for manufacturing a substrate according to a conventional example.

FIGS. 10A and 10B are perspective and plan views showing a normal chip component.

FIGS. 11A and 11B are perspective and plan views showing an LW reversal type chip component.

FIGS. 12A and 12B are a sectional view showing the case in which the LW reversal type chip component is built in the substrate according to the conventional example and a view for explaining resin filling.

FIG. 13 is a sectional view showing the case in which a clearance of the substrate according to the conventional example is made bulky.

### DETAILED DESCRIPTION OF THE PREFERRED EMBODIMENTS

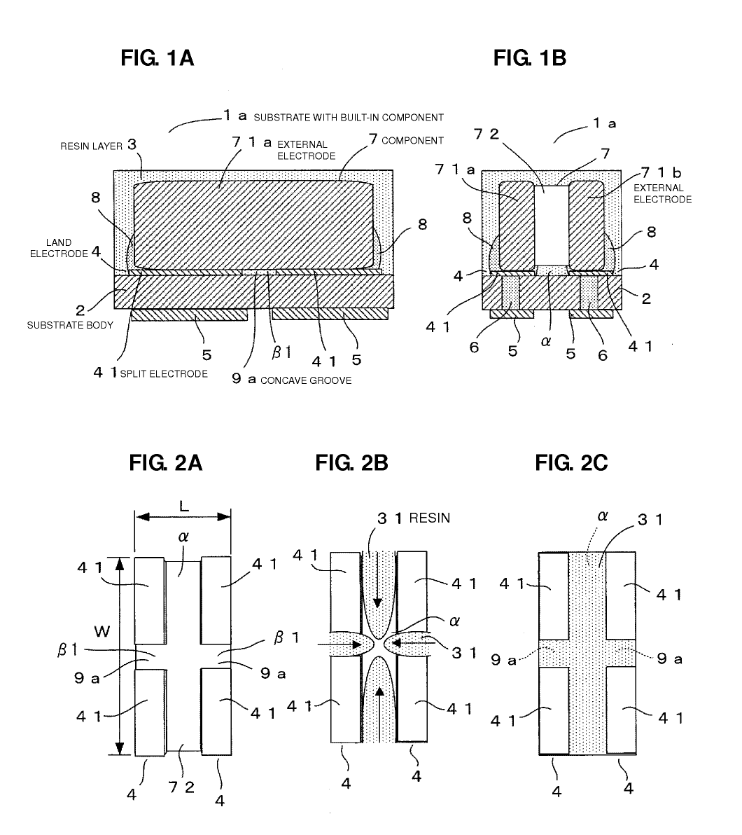

Preferred embodiments of a substrate with a built-in component according to the present invention will be described in detail with reference to FIGS. 1A to 8.

### First Preferred Embodiment

A first preferred embodiment including a core board will be described with reference to FIGS. 1A through 2C.

FIGS. 1A and 1B show a substrate with a built-in component 1a according to the present preferred embodiment, and the substrate with a built-in component 1a is preferably formed by laminating a resin layer 3 on a substrate body 2 to be a core board.

The substrate body 2 is a base body preferably made of a glass epoxy substrate according to an example of a multilayer/single layer wiring board, for example, and a land electrode 4 to be a component mounting electrode according to a preferred embodiment of the present invention is formed on an upper surface by printing or the like, a lower electrode 5 is formed on a lower surface by the printing or the like, and the land electrode 4 and the lower electrode 5 are connected to each other through a through-type via conductor 6 in the substrate body 2, for example.

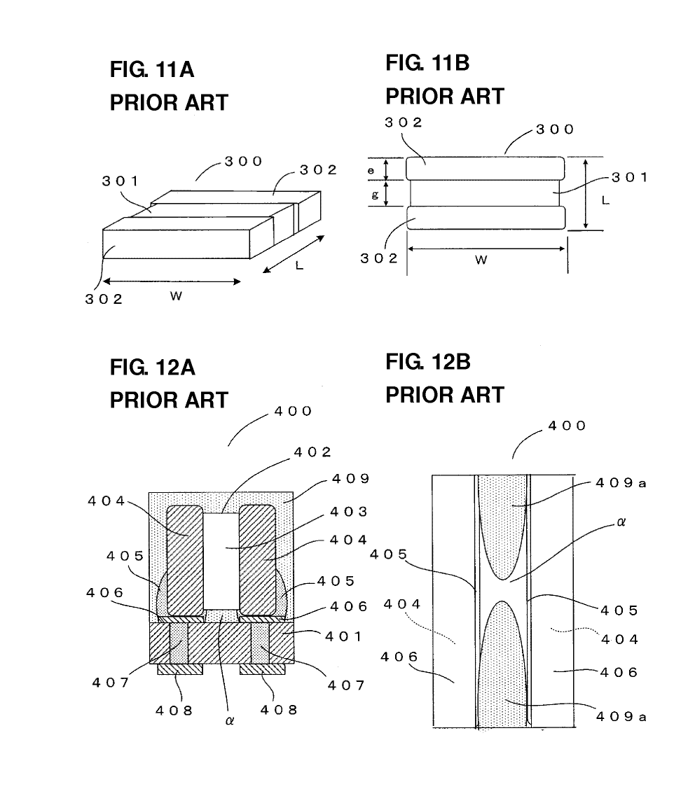

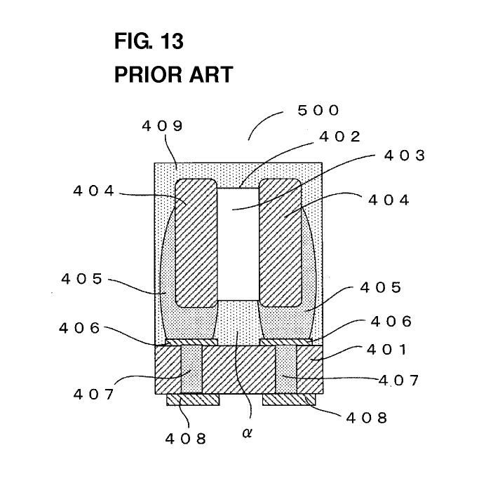

A component 7 is mounted on an upper surface side (a mounting surface side) of the substrate body 2. Although the component 7 may include various components built in the resin layer 3, preferably the component is an LW reversal type chip component preferably having a rectangular or substantially rectangular parallelepiped shape, and more specifically, preferably is the same LW reversal type chip capacitor (for example, an L size: 0.8 mm, a W size: 1.6 mm, a height of 0.5 mm) as the chip capacitor 300 shown in FIGS. 11A and 11B, for example.

The component 7 includes external electrodes 71a and 71b in the W size located on surfaces provided in contact with two long sides of a rectangular or substantially rectangular mounting surface (lower surface) respectively, and preferably has a shape such that a body portion 72 is interposed between the external electrodes 71a and 71b.

The external electrodes 71a and 71b are connected to the respective land electrodes 4 through a bonding material 8 such as a solder.

In the LW reversal type chip capacitor of the component 7, L<W is set and the W size is large as described above, and furthermore, a g size is small. For this reason, when the land electrodes 4 of the external electrodes 71a and 71b are formed in a continuous copper foil pattern or the like along the external electrodes 71a and 71b respectively, the external electrodes 71a and 71b are bonded to the respective land electrodes 4 through the bonding material 8 so that the component 7 is mounted. Consequently, a slender bottleneck-shaped clearance α interposed between the external electrodes 71a and 71b is formed on the lower side of the component 7 and there is a possibility that an uncured (semicured) resin might not sufficiently go around the clearance α in the formation of the resin layer 3.

In a preferred embodiment of the present invention, therefore, a plurality of split electrodes 41 is arranged in a vertical line to define the land electrodes 4 of the respective external electrodes 71a and 71b, and a concave groove 9a in a transverse direction in which the resin flows is defined by a clearance β1 between the split electrodes 41.

More specifically, in the present preferred embodiment, each land electrode 4 preferably includes two split electrodes 41 constituted by a copper foil having a foil thickness of about 18 μm as shown in FIG. 2A, for example, and the concave groove 9a is located under a central portion in a longitudinal direction of each of the external electrodes 71a and 71b.

In this case, when the external electrodes 71a and 71b are bonded to the respective split electrodes 41 through the bonding material 8 such as a solder so that the component 7 is mounted, the clearance β1 of the concave groove 9a through which an uncured resin 31 flows is located on the lower side of the component 7 in communication with the clearance α. Each split electrode 41 is connected to the opposed lower electrode 5 through the via conductor 6, for example.

The resin layer 3 is preferably formed by heating and pressing a thermosetting epoxy resin sheet containing an inorganic filler to approximately 180° C., by thermocompression bonding (heating and pressing) in a vacuum environment as described above, for example. The uncured (or semicured) resin 31 is expanded in downward and transverse directions by the heating and pressing so that the component 7 is embedded in the resin 31, and the resin 31 is cured in this state so that the resin layer 3 is formed.

The uncured resin 31 thus expanded by the heating and pressing enters the clearance α in the lower portion of the component 7 from the concave groove 9a of the clearance β1 as well as the end surfaces of the external electrodes 71a and 71b as shown in a state brought during resin filling in FIG. 2B as seen from the lower surface side of the component 7. For this reason, the resin 31 reliably goes around and is thus filled in the clearance α as shown in a state brought after the completion of the filling in FIG. 2C as seen from the lower surface side of the component 7.

In other words, in the present preferred embodiment, the concave groove 9a in the transverse direction preferably is defined by the clearance β1 between the split electrodes 41 forming the land electrodes 4 of the substrate body 2. When the component 7 of the LW reversal type chip capacitor which is mounted is to be embedded in the resin layer 3, consequently, the clearance α is not made bulky with an expansion in a height direction but the uncured resin 31 passes through the concave groove 9a and sufficiently goes around the slender bottleneck-shaped clearance α on the lower side of the component 7 so that the resin is reliably filled in the clearance α. Accordingly, it is possible to provide the substrate with a built-in component 1a including a core board structure in which a defect such as a solder flash of reflow is not caused.

### Second Preferred Embodiment

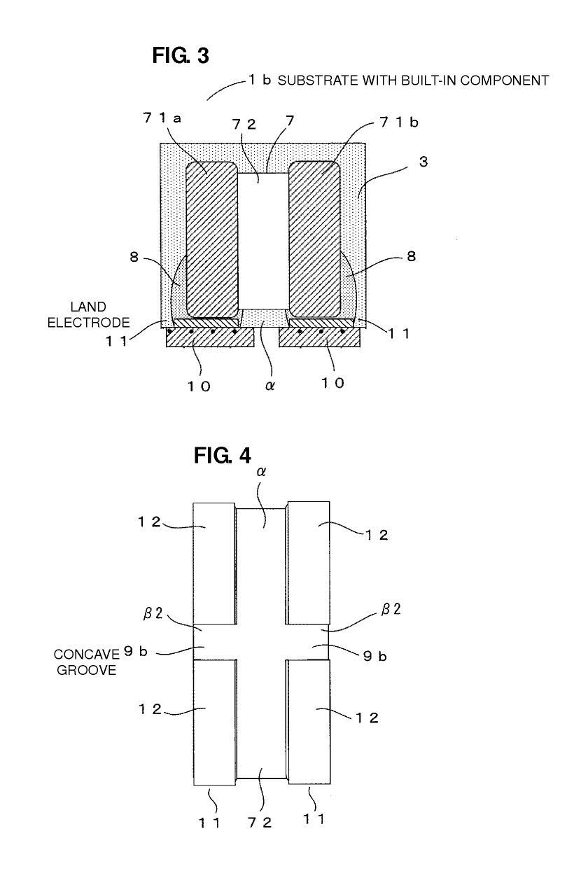

A second preferred embodiment of the coreless substrate structure including no substrate body 2 will be described with reference to FIGS. 3 to 5E.

FIG. 3 shows a substrate with a built-in component 1b according to the present preferred embodiment. In FIG. 3, the same reference numerals in FIGS. 1A, 1B and 2A-2C indicate the same or corresponding portions. In the substrate with a built-in component 1b, a metal plate 10 is provided as a base body on a lower side of external electrodes 71a and 71b of a component 7. The metal plate 10 is preferably made of a copper foil treated in a state of poor wettability such that a solder is expanded with wetting over a surface by a surface treatment with difficulty. A land electrode 11 to be a component mounting electrode according to a preferred embodiment of the present invention is preferably formed by copper plating over the metal plate 10, for example. Then, the external electrodes 71a and 71b of the component 7 are bonded to the land electrode 11 through a bonding material 8 such as a solder so that the component 7 is mounted thereon. Furthermore, a resin layer 3 is laminated on the metal plate 10 to cause the component 7 to be built in. Thus, the substrate with a built-in component 1b including the coreless board structure is formed.

Also in the substrate with a built-in component 1b, the land electrode 11 provided on the metal plate 10 preferably includes a plurality of (two in the drawing) split electrodes 12 extending along a vertical line as shown in FIG. 4 and a clearance β2 between the split electrodes 12 defines a concave groove 9b in a transverse direction such that a resin of the uncured resin layer 3 goes around a clearance α provided in a lower portion of the component 7.

In the formation of the resin layer 3, therefore, the uncured resin flows through the concave groove 9b and thus enters the clearance α provided between the external electrodes 71a and 71b so that the resin is reliably filled in the clearance α. Consequently, the substrate with a built-in component 1b produces the same advantageous effects as those in the substrate with a built-in component 1a according to the first preferred embodiment.

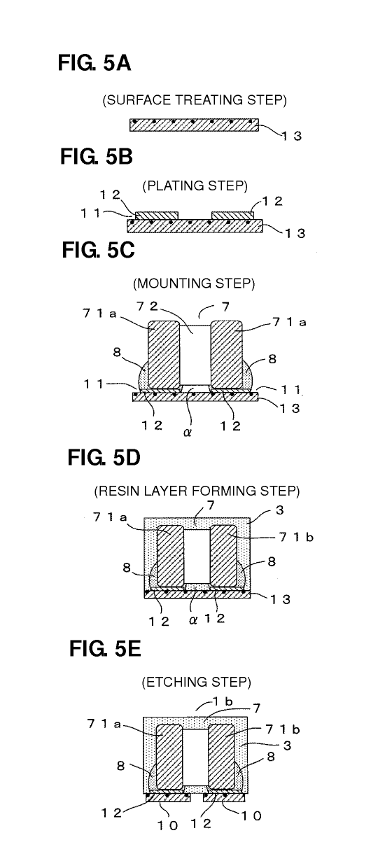

Next, a non-limiting example of a method of manufacturing the substrate 1b with a built-in component will be described with reference to sectional views showing end surfaces in FIGS. 5A to 5E.

First of all, in a surface treating step shown in FIG. 5A, a copper foil 13 is prepared. The copper foil 13 is subjected to a surface treatment in which a solder is not expanded with wetting. In the drawing, “.” indicates a surface treatment.

In a plating step shown in FIG. 5B, next, the split electrode 12 in a vertical line defining the land electrode 11 is provided, by copper plating (for example, a thickness of about 12 μm), on the treated surface of the copper foil 13.

In a mounting step shown in FIG. 5C, furthermore, solder mounting is carried out over the split electrode 12 by using an LW reversal type chip capacitor (for example, an L size: 0.8 mm, a W size: 1.6 mm, a height of 0.5 mm) as the component 7.

In a resin layer forming step shown in FIG. 5D, subsequently, an embedding resin (a thermosetting resin) is disposed on an upper surface of the mounted component 7 and is thus subjected to thermocompression bonding (heating and pressing) in a vacuum environment. At this time, the uncured resin goes around the clearance α on the lower side of the component 7 from the concave groove 9b between the split electrodes 12 and is thus filled well so that the resin layer 3 is formed.

In an etching step shown in FIG. 5E, the copper foil 13 is then etched into the metal plate 10 having a larger size than each split electrode by a length and a breadth of about 0.1 mm, for example, so that the substrate with a built-in component 1b is manufactured.

In the present preferred embodiment, accordingly, the resin goes around the lower portion of the component 7 well and is thus filled reliably by the concave groove 9b provided between the split electrodes 12 in the manufacture of the substrate with a built-in component 1b including a coreless board structure which is advantageous to a reduction in a height. Consequently, it is possible to provide the substrate with a built-in component 1b in which the resin is filled well in the lower side of the component 7. Thus, it is possible to prevent an occurrence of a drawback such as a solder flash in the subsequent reflow of the substrate with a built-in component 1b.

### Third Preferred Embodiment

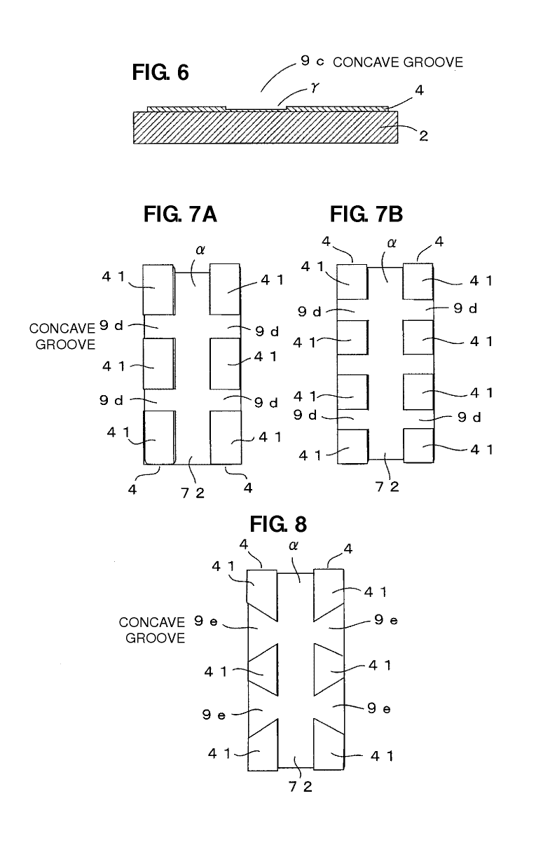

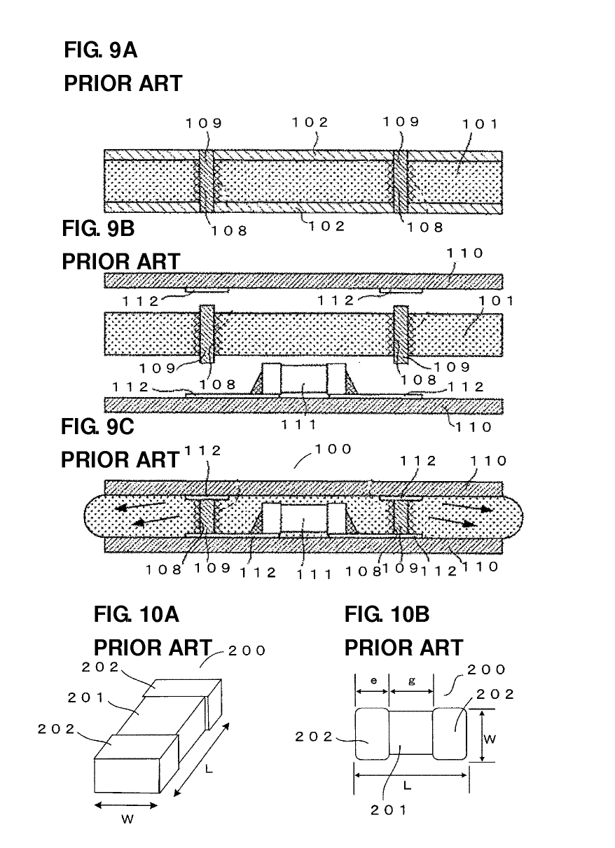

Next, a third preferred embodiment to be a variant of the first and second preferred embodiments will be described with reference to FIG. 6.

In the present preferred embodiment, the concave groove according to the present invention is not defined by the clearances β1 and β2 provided between the split electrodes as in the first and second preferred embodiments but is preferably defined by a dent obtained by carrying out half etching or the like over the component mounting electrode according to a preferred embodiment of the present invention.

FIG. 6 is a sectional view showing the case in which the land electrode 4 according to the first preferred embodiment is applied. In the land electrode 4, a dent γ is formed by the half etching or the like in a central portion and a concave groove 9c is defined by the dent γ.

Also in the case in which the concave groove 9c is thus formed, it is possible to obtain the same advantageous effects as those in the first and second preferred embodiments.

The present invention is not restricted to the preferred embodiments but various changes can be made in addition to the foregoing without departing from the gist thereof. For example, the component mounting electrode according to the present invention is not restricted to the land electrode. Moreover, the number of the concave grooves in the component mounting electrode may be increased to be two, three and the like depending on a length of the electrode. FIGS. 7A and 7B are views for explaining the case in which two concave grooves 9d and three concave grooves 9d are provided depending on the split electrode 41 respectively, for example.

Moreover, the shapes or widths of the concave grooves 9a to 9d may be varied as desired. For example, it is preferable that an outside is wider than a clearance α side (an inside) to cause the resin to flow into the clearance α more easily as shown in a concave groove 9e of FIG. 8.

Next, the resin layer 3 may be formed by a photocuring resin or other suitable process. Moreover, the component 7 may be various LW reversal type (L<W) chip components other than the chip capacitor, a normal (L>W) chip component or an electronic component other than the chip component, and furthermore, a module component such as a CPU (MPU) and the like. For example, it is preferable that the present invention may be applied to the normal chip component having a large mounting area.

In addition, the present invention can also be applied to a multilayer substrate with a built-in component in which the substrates with built-in components 1a and 1b in FIGS. 1A, 1B and 3 are provided as multilayers, for example.

Preferred embodiments of the present invention can be applied to a substrate with a built-in component for various purposes.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A substrate with a built-in component, comprising:
a component to be embedded in a resin layer; and
a component mounting electrode to which an external electrode of the component is bonded; wherein
the component mounting electrode includes a concave groove through which an uncured resin of the resin layer flows in a transverse direction.

2. The substrate with a built-in component according to claim 1, wherein the component mounting electrode includes a plurality of split electrodes arranged along a vertical line, and the concave groove is defined by a clearance provided between the plurality of split electrodes.

3. The substrate with a built-in component according to claim 1, wherein the component mounting electrode has an elongated rectangular or substantially rectangular shape, and the concave groove extends in a direction that is perpendicular or substantially perpendicular to a long side of the component mounting electrode.

4. The substrate with a built-in component according to claim 1, wherein the component has a rectangular or substantially parallelepiped shape, and has a structure in which the external electrode is located on respective surfaces arranged in contact with two long sides of a rectangular or substantially rectangular mounting surface.

5. The substrate with a built-in component according to claim 4, wherein the component is a chip capacitor with a rectangular or substantially rectangular parallelepiped shape.

6. The substrate with a built-in component according to claim 1, wherein the substrate includes a substrate body defined by a glass epoxy substrate.

7. The substrate with a built-in component according to claim 6, wherein the component mounting electrode is located on a top surface of the substrate body, and a lower electrode is located on a lower surface of the substrate body and connected to the component mounting electrode through a via conductor extending through the substrate body.

8. The substrate with a built-in component according to claim 1, wherein the component is an LW reversal type chip component.

9. The substrate with a built-in component according to claim 1, wherein the component has a length dimension of about 0.8 mm, a width dimension of about 1.6 mm, and a height dimension of about 0.5 mm.

10. The substrate with a built-in component according to claim 1, wherein the component includes at least two external electrodes arranged to define a slender bottleneck-shaped clearance therebetween.

11. The substrate with a built-in component according to claim 10, wherein the concave groove is located under a central portion in a longitudinal direction of each of the at least two external electrodes.

12. The substrate with a built-in component according to claim 2, wherein the plurality of split electrodes includes at least two split electrodes each made of a copper foil having a foil thickness of about 18 μm.

13. The substrate with a built-in component according to claim 1, wherein the substrate includes a metal plate made of a copper foil.

14. The substrate with a built-in component according to claim 13, wherein the component mounting electrode includes a copper plating film located on the metal plate.

15. The substrate with a built-in component according to claim 1, wherein the concave groove is defined by a dent in the component mounting electrode.

16. The substrate with a built-in component according to claim 1, wherein the concave groove includes a plurality of concave grooves located in the component mounting electrode.

17. The substrate with a built-in component according to claim 1, wherein the component is a chip component or a module component.

18. The substrate with a built-in component according to claim 1, wherein the substrate includes a substrate body that is a multi-layer substrate.

19. The substrate with a built-in component according to claim 1, wherein the substrate includes a substrate body that is a single layer substrate.
